(19) United States
(12) Patent Application Publication
(10) Pub. No.: US 2012/0074974 A1
(43) Pub. Date: Mar. 29, 2012

(54) Test Unit and Test System

(76) Inventors: Yohei Sato, Tokyo (JP); Kenichi Kataoka, Yamanashi (JP)

(21) Appl. No.: 13/375,588

(22) PCT Filed: May 27, 2010
(86) PCT No.: PCT/JP2010/059400

§ 371 Date: Dec. 2, 2011

Related U.S. Application Data
(60) Provisional application No. 61/183,349, filed on Jun. 2, 2009.

(51) Int. Cl. G01R 1/04; G01R 1/067

(52) U.S. Cl. 324/750.16; 324/756.03

(57) ABSTRACT

A test unit to be used with a tester that tests an electrical characteristic of a circuit formed in a wafer includes a tester a board electrically connected to the tester; a first wireless port mounted on a lower surface of the tester board and electrically connected to the tester; a probe board that includes a probe to be in contact with an electrode pad of the electronic circuit, and is configured so that the probe board may be transferred along with the wafer into the system box while the probe and the electrode pad are in contact with each other; a second wireless port that is mounted on an upper surface of the probe board and electrically connected to the probe, and carries out contactless transmission/reception with the first wireless port; a chuck plate that is away from the tester board, and holds the probe board and the wafer; and a flexible expandable chamber that may be inflated by introducing gas thereinto.

### TECHNICAL FIELD

The present invention relates to a test unit that tests electronic characteristics of electronic circuits fabricated in an integrated circuit, and a test system employing the test unit.

### BACKGROUND ART

Electronic circuits such as integrated circuits (ICs) fabricated on a semiconductor wafer (referred to as a wafer hereinafter) are tested using a probe apparatus, which includes a susceptor on which the wafer subject to testing is placed and a probe board that has plural probes (contactors) to be in contact with corresponding electrode pads of the electronic circuits on the wafer and outputs test signals from a tester to the corresponding probes.

One way of reducing cost in testing the electronic circuits is to simultaneously test all electronic circuits of the IC wafer (referred to as a device under test DUT). This way of testing may be referred to as full wafer contact and test. In the full wafer contact and test, the probe board is provided with the probes corresponding to all the electrode pads of the electronic circuits on the wafer, and the electronic circuits are collectively tested while all the probes are in contact with the corresponding electrode pads (see Patent Document 1, for example).

Patent Document 1: Japanese Patent Publication No. 3303968

### SUMMARY OF INVENTION

### Problems to be Solved by the Invention

Incidentally, decreasing circuit patterns due to advancing improvements in circuit fabrication technology lead to an increasing number of ICs on the wafer, and complicating IC functions lead to an increasing number of electrodes pads per IC. Therefore, the total number of the electrode pads on the wafer is largely increased, which lengthens a testing time even in the full wafer contact and test method and may result in an increasing testing cost.

In addition, as the number of the electrode pads of an IC on the wafer is increased, the number of the electrode pads corresponding to the electrode pads on the probe board is accordingly increased, and thus a large number of the probes are in contact with a corresponding number of the electrodes between the probe board and the wafer. When a probe is in contact with an electrode pad, an assured electrical contact between the probe and the electrode pad is not realized unless the probe goes through a native oxidation film formed on the electrode pad. Therefore, greater force needs to be applied between the probe board and the wafer, as the number of the electrode pads and the corresponding probes are increased.

Moreover, an increasing number of the probes require a large number of wirings that electrically connect the tester and the probes. Because such wirings extend from a periphery of the probe board to the corresponding probes, a problem of insufficient space for the wirings is caused. In addition, because different wirings have different lengths depending on locations of the probes (for example, a wiring connecting to a probe located around the center of the wafer is longer than a wiring connecting to a probe located near a circumferential edge of the wafer), a problem may be caused in that the test signals output from the tester are out of synchronization, which may impair appropriate testing of the wafer.

The present invention has been made in view of the above, and provides a test unit that enables appropriate full wafer contact and test in electronic circuits fabricated on a wafer.

### Means of Solving the Problems

A first aspect of the present invention provides a test unit to be used with a tester that tests an electrical characteristic of an electronic circuit formed in a wafer. The test unit includes a tester board that is accommodated in a system box and electrically connected to the tester; a first wireless port that is mounted on a lower surface of the tester board and electrically connected to the tester; a probe board that includes a probe to be in contact with an electrode pad of the electronic circuit, and is configured so that the probe board may be transferred along with the wafer into the system box while the probe and the electrode pad are in contact with each other; a second wireless port that is mounted on an upper surface of the probe board electrically connected to the probe, and carries out contactless transmission/reception with the first wireless port; a chuck plate that is accommodated in the system box in order to be away from the tester board, and holds the probe board and wafer transferred into the system box; and an expandable chamber having flexibility that allows the expandable chamber to be inflated by introducing gas thereinto, thereby applying pressure onto the probe board and wafer held by the chuck plate. The first wireless ports are arranged in order to face the corresponding second wireless ports via the expandable chamber, and test signals are contactlessly transmitted/received through the expandable chamber by the first and the second wireless ports.

A second aspect of the present invention provides a test system that includes a test unit according to the first aspect, an alignment unit that aligns the electrode pad of the electronic circuit fabricated on the wafer with the probe of the probe board and temporarily fixes the probe board and the wafer; and a transfer unit that transfers the temporarily fixed probe board and wafer to the test unit.

### BRIEF DESCRIPTION OF THE DRAWINGS

FIG. 1 is a schematic view illustrating a test unit according to a first embodiment.

FIG. 2 is an explanatory view depicting operations of testing electronic circuits subject to testing.

FIG. 3 is another explanatory view for depicting the operations of testing the electronic circuits subject to testing, in succession to FIG. 2.

FIG. 4 is a schematic view illustrating a test system according to a second embodiment of the present invention.

FIG. 5 is a schematic cross-sectional view illustrating a mechanism that enables temporary fixture of a probe board and a device under test.

### MODE(S) FOR CARRYING OUT THE INVENTION

Non-limiting, exemplary embodiments of the present invention will now be described with reference to the accompanying drawings. In the drawings, the same or corresponding reference symbols are given to the same or corresponding members or components, and undue explanations are omitted.

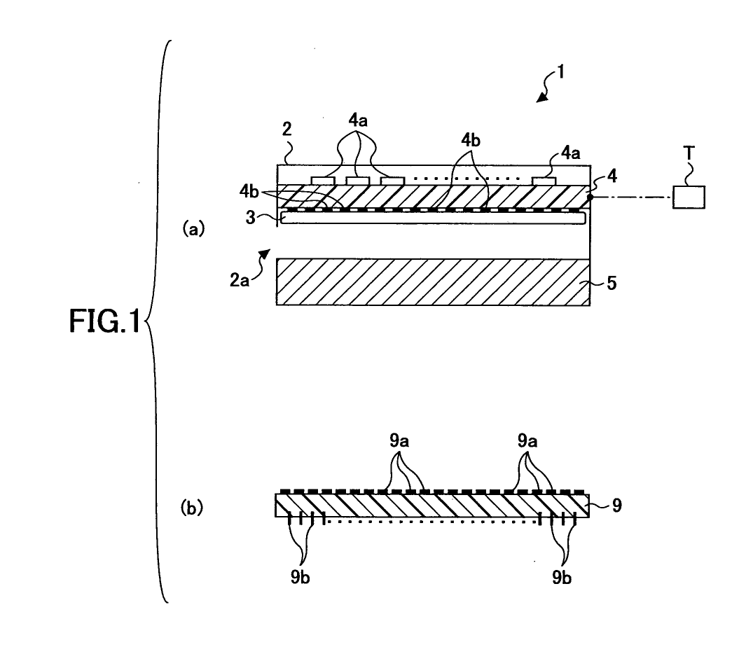

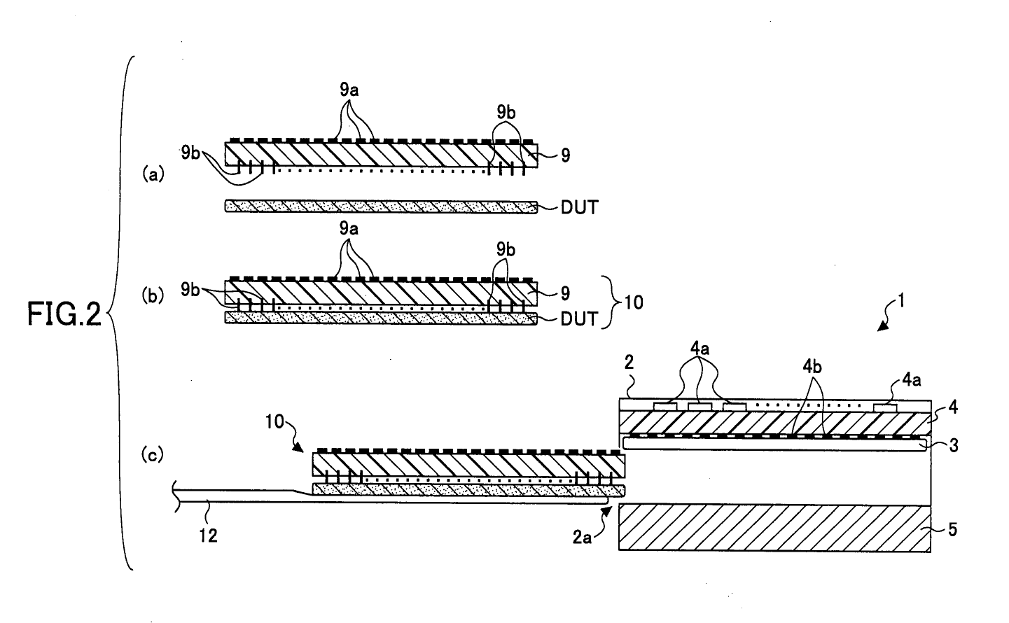

FIG. 1 is a schematic view illustrating a test unit according to an embodiment of the present invention. Referring to a subsection of FIG. 1, a test unit 1 according to this embodiment includes a tester board 4 that is accommodated inside a system box 2 and is electrically connected to a tester T, an expandable chamber 3 attached on a lower surface of the tester board 4, and a chuck plate 5 that holds a probe board 9 and a wafer subject to testing (referred to as a device under test DUT hereinafter) that are held with each other so that probes 9b of the probe board 9 are in contact with corresponding electrode pads of the device under test DUT. For the sake of explanation, the probe board 9 and the device under test DUT that are held in such a manner are referred to as a shell 10 (see a subsection (a) of FIG. 2), hereinafter.

The system box 2 has a box shape, and has an opening portion 2a on one side wall, the opening portion 2a corresponding to a space between the expandable chamber 3 and the chuck plate 5. The shell 10 is transferred into/out from the system box 2 through the opening portion 2a. The opening portion 2a may be provided with an openable/closable door. In addition, an electrical power unit and a test temperature control unit may be provided inside the system box 2.

The tester board 4 provides electronic functions for testing the device under test. For example, the tester board 4 may be configured of a printed circuit board, a ceramic printed circuit board, or the like, and have modules or electronic components (and/or integrated circuits) 4a. In addition, the tester board 4 may be connected to a controller for testing the wafer and an electric power supplier, which are not shown. The tester board 4 is provided on its lower surface with wireless ports 4b that perform contactless transmission/reception with wireless ports 9a provided on an upper surface of the probe board 9. The wireless ports 4b are transmitter/receiver components having predetermined transmitter/receiver circuits, not limited to a particular one, but may be chosen depending on types of the device under test DUT or the like. Moreover, the wireless ports 4b may be fabricated directly in the tester board 4 by an IC fabrication technology, or the wireless ports 4b configured as one or plural independent electronic components may be attached on the tester board 4.

The modules or electronic components 4a are electrically connected with the wireless ports 4 by way of through electrodes or via plugs (not shown) that go through the tester board 4. The through electrodes or via plugs may be formed by filling through holes formed in the tester board 4 with electrically conductive paste and heating the electrically conductive paste. In addition, the through electrodes or via plugs may be formed be of solder balls.

The tester board 4 has a size larger than or equal to the size of the device under test DUT, which makes it possible to simultaneously test all the electronic circuits in the device under test DUT.

The expandable chamber 3 is provided, or firmly fixed on the lower surface of the tester board 4. The expandable chamber 3 is made of material having flexibility, including resins such as polyimide and poly ester, or rubber, and has substantially the same size as the tester board 4. A predetermined inlet/outlet port (not shown) is formed in the expandable chamber 3. The expandable chamber 3 is made airtight, except that gaseous communication with an outer environment of the expandable chamber 3 is allowed only through the inlet/outlet. In fact, the inlet/outlet port is connected to a predetermined pressure control unit (not shown). When compressed gas is introduced into the expandable chamber 3 from the pressure control unit through the inlet/outlet port, the expandable chamber 3 is inflated, and thus the probe board 9 (described later) is pressed downward, which makes the probes 9b of the probe board 9 to come in stable contact with the corresponding electrode pads of the device under test DUT. Therefore, reliable testing is realized.

The probe board 9 (a subsection (b) of FIG. 1) may be made of, for example, materials such as silicon, ceramic materials, and organic materials. The probe board 9 includes on an upper surface plural wireless ports 9a acting as transmitter/receiver components including predetermined transmitter/receiver circuits, and on a lower surface plural probes 9b to be in contact with the corresponding electrode pads of the device under test DUT. The wireless ports 9a carry out contactless transmission/reception with wireless ports 4b provided on the lower surface of the tester board 4. The wireless ports 9a are electrically connected to the corresponding probes 9b by way of through electrodes or via plugs (not shown) formed in the probe board 9. In addition, the probe board 9 is provided with alignment marks or alignment pins for aligning the probes 9b with the corresponding pads of the device under test DUT.

Incidentally, the wireless ports 9a may be fabricated directly in the probe board 9 by an IC fabricating technology. Alternatively, wireless ports 9a configured as independent one or plural electronic components are attached on the probe board 9.

In addition, contactless transmission/reception between the wireless ports 4b and the wireless ports 9a may be realized by various communication technologies such as a near-field communication, and a radio-frequency (RF) communication, depending on a distance between the wireless ports 4b and the wireless ports 9a, frequencies or pulse intervals of the signals to be contactlessly transmitted/received, the number of signals to be contactlessly transmitted/received, or the like, and the wireless ports 4b and the wireless ports 9a are selected based on the communication technologies. For example, when the distance between the wireless ports 4b and the wireless ports 9a is relatively small and a relatively large number of the wireless ports 4b and the wireless ports 9a are used, the near-field communication is preferable because this communication technology allows communications at an extremely close range, thereby reducing cross talk from another nearby wireless ports 4b or wireless ports 9a. Alternatively, when the distance between the wireless ports 4b and the wireless ports 9a is relatively large, the RF communication technology is preferable. Moreover, when plural signals are simultaneously transmitted/received, a frequency division multiplexing (FDM) technology or a time division multiplexing (TDM) technology may be used.

In addition, the probe board 9 has a size larger than or equal to the size of the device under test DUT, and has the probes 9b corresponding to all the electrode pads of all the electronic circuits in the device under test DUT. Therefore, all the electronic circuits in the device under test DUT can be simultaneously collectively tested.

The chuck plate 5 is provided away from the tester board 4 inside the system box 2, and holds the shell 10 that is transferred into the system box 2 by a transfer arm 12 (a subsection (c) of FIG. 2). In this case, the shell 10 is held by the chuck plate 5 so that the device under test DUT faces or contacts an upper surface of the chuck plate 5. In addition, the chuck plate 5 is provided with guide pins (not shown), so that the shell 10 is placed in an appropriate position by the guide pins. The chuck plate 5 is connected to a vacuum apparatus (not shown), and thus holds the shell 10 on the upper surface of the chuck plate 5 by suction. In addition, the chuck plate 5 is movable in a vertical direction, and is configured to withstand force (described later) applied onto the shell 10 on the upper surface of the chuck plate 5 by the expandable chamber 3. Moreover, the chuck plate 5 may include a temperature control mechanism (not shown) for testing the device under test DUT at a predetermined temperature. With this, the device under test DUT can be tested at a temperature, for example, ranging from 40° C. through 150° C. Incidentally, the chuck plate 5 is not necessarily movable in the vertical direction in other embodiments, which is preferable in that the chuck plate 5 can more easily withstand the force applied onto the shell 10 on the chuck plate 5.

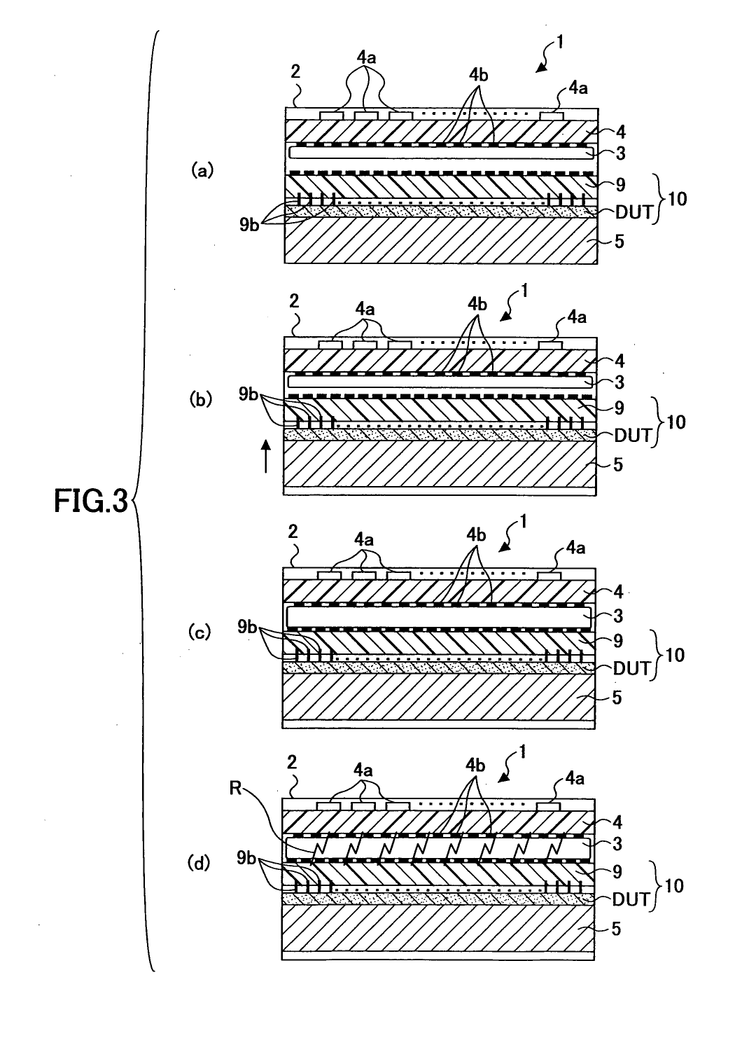

Next, operations of the test unit 1 according to this embodiment are explained with reference to FIGS. 2 and 3.

First, the probe board 9 and the device under test DUT are arranged to face each other, and the probes 9b of the probe board 9 are aligned with the corresponding electrode pads of the device under test DUT, as shown in a subsection (a) of FIG. 2. This alignment may be carried out by using the alignment marks formed on the device under test DUT and corresponding alignment marks formed on the probe board 9. Such alignment is preferably carried out in, for example, an alignment unit.

Next, the probe board 9 and the device under test DUT are held with each other while the probes 9b of the probe board 9 are in contact with the corresponding electrode pads, and thus the shell is configured. Not being limited to this, the shell 10 is preferably configured by temporarily fixing the probe board 9 and the device under test DUT. Such temporary fixture may be realized by evacuating a space between the probe board 9 and the device under test DUT to a reduced pressure, as described later. In addition, the temporary fixture may be realized by holding the probe board 9 and the device under test DUT with magnets from both sides. In this case, it is preferable that the magnets are buried in a circumferential portion of the lower surface of the probe board 9, and the corresponding magnets are placed on the lower surface of the device under test DUT after the alignment is made, thereby holding the probe board 9 and the device under test DUT. Moreover, the temporary fixture may be realized by clipping the probe board 9 and the device under test DUT with a predetermined clipping jig.

The shell 10 is preferably transferred into the test unit 1 as shown in the subsection (c) of FIG. 2, and placed on the chuck plate 5, as shown in a subsection (a) of FIG. 3. At this time, the shell 10 is placed in an appropriate position by the guide pins (not shown) provided on the chuck plate 5 and/or due to transferring accuracy of the transfer arm 12 (FIG. 2). Next, the shell 10 is firmly held on the chuck plate 5 by suction.

Next, the chuck plate 5 is moved upward so that the probe board 9 of the shell 10 is located with a predetermined distance in relation to the expandable chamber 3, as shown in a subsection (d) of FIG. 2. Then, when compressed gas at a pressure of about 1.13 kg/cm2 is introduced into the expandable chamber 3 from the pressure control unit (not shown), the expandable chamber 3 is inflated to apply a downward force onto the probe board 9 of the shell 10. At this time, the downward force of about 800 kgf is applied onto the probe board 9, and thus the same force is applied onto the device under test DUT. The downward force may correspond to about 10 gf for each of the probes 9b, assuming that there are about 80,000 probes 9b in the probe board 9, and is sufficient for the probes 9b to go through a native oxidation film formed on the electrode pads of the device under test DUT to reach the metal constituting the electrode pads. Therefore, stable ensured electric contacts of the probes 9b of the probe board 9 with the corresponding electrode pads of the device under test DUT are realized.

Then, when the test signals are output to the tester board 4 from the tester T (the subsection (a) of FIG. 1), the test signals undergo predetermined processes in the modules or electronic components 4a and are transmitted from the wireless ports 4b to the corresponding wireless ports 9a through the expandable chamber 3. Next, the test signals received by the wireless ports 9a are output to the corresponding probes 9b, and input to corresponding electronic circuits subject to testing through the electrode pads, with which the corresponding probes 9b are in contact, of the device under test DUT.

Upon receiving the test signals, the electronic circuits subject to testing output output-signals based on the input test signals to predetermined electrode pads. The output signals are input to the wireless ports 9a from the predetermined electrode pads to the probes 9b, and transmitted from the wireless ports 9a to the wireless ports 4b through the expandable chamber 3.

The output signals received by the wireless ports 4b are output to the modules or electronic components 4a, undergo predetermined processes, and are output to the tester T (FIG. 1) from the tester board 4. The tester T compares the output signals from the electronic circuits of the device under test DUT with the test signals that have been first output from the tester T, thereby determining whether the electronic circuits subject to testing are normally operating. In such a manner, the device under test DUT is tested.

According to the test unit 1 of this embodiment, because the test signals from the tester T and the output signals from the electronic circuits subject to testing are contactlessly transmitted/received between the wireless ports 4b mounted on the lower surface of the tester board 4 and the wireless ports 9a mounted on the upper surface of the probe board 9, a need for the wirings electrically connecting the probes and the tester can be eliminated. Therefore, a problem of insufficient space for such wirings, which may be caused along with a decreasing circuit size and an increasing wafer size, can be solved. In addition, because a need for providing the wirings in a narrow space can be eliminated, production cost can be reduced.

Moreover, the probes 9b of the probe board 9 are aligned with the corresponding electrode pads of the device under test DUT and the probe board 9 and the device under test DUT are formed into the shell 10 outside the test unit 1, in this embodiment. Therefore, time required for such alignment can be reduced compared to a case where the probes 9b of the probe board 9 are aligned with the corresponding electrode pads of the device under test DUT and the probe board 9 and the device under test DUT are formed into the shell 10 inside the test unit 1, thereby contributing to prompt testing.

Moreover, because the signals are contactlessly transmitted/received between the wireless ports 4b and the wireless ports 9a, a need for strict alignment between the tester board 4 and the shell 10 can be eliminated, and the tester board 4 and the shell 10 can be aligned only with the guide pins provided in the chuck plate 5 and/or due to the transferring accuracy of the transfer arm 12, thereby further contributing to prompt testing.

In addition, the probe board 9 may have a fan-out function for re-wiring the electrode pads of the device under test DUT. With this, distances between the electrode pads are alleviated, and the number of the electrode pads is apparently reduced, and thus time for the testing can be reduced.

Moreover, there are no large differences in terms of length between electrical paths from the wireless ports 9a through the probes 10. Therefore, a problem of out-of-synchronization of signals, which may be caused from the differences in length between the electrical paths, can be solved.

Furthermore, when various probe boards 9 are prepared depending on the devices under test DUT, various devices under test DUT can be tested just by selecting the probe boards 9 in accordance with the devices under test DUT, without modifying the test unit 1.

In addition, the wireless ports 4b and/or the wireless ports 9a may have a signal correction function. With such a function, wave-forms of the test signals from the tester and the output signals from the electronic circuits subject to testing formed in the device under test DUT can be corrected by the wireless ports 4b and/or the wireless ports 9a rather than by the tester. Therefore, signal processing loads of the tester can be reduced, thereby improving testing reliability.

Incidentally, the modules or electronic components 4a mounted on the upper surface of the tester board 4 may have the correction function, instead of the wireless ports 4b.

Moreover, because the test unit 1 according to this embodiment includes the expandable chamber 3, the probes 9b can assuredly come in contact with the corresponding electrode pads of the device under test DUT substantially throughout the device under test DUT by introducing the high-pressure compressed gas into the expandable chamber 3 from a pressure control unit (not shown). Therefore, the device under test DUT can be assuredly tested. Moreover, because the probe board 9 is pressed downward by the expandable chamber 3 inflated by the introduced compressed gas, height differences between the electrode pads of the device under test DUT and/or deflection of the device under test DUT can be compensated for when the probe board 9 is made flexible, thereby assuredly contacting the probes 9b with the electrode pads of the device under test DUT.

Furthermore, the probes 9b of the probe board 9 are pressed onto the corresponding electrode pads of the device under test DUT with sufficient force by introducing the high-pressure compressed gas into the expandable chamber 3. In addition, there is no need for an extensive mechanism in order to press the probes 9b onto the corresponding electrode pads, thereby making the test unit 1 compact.

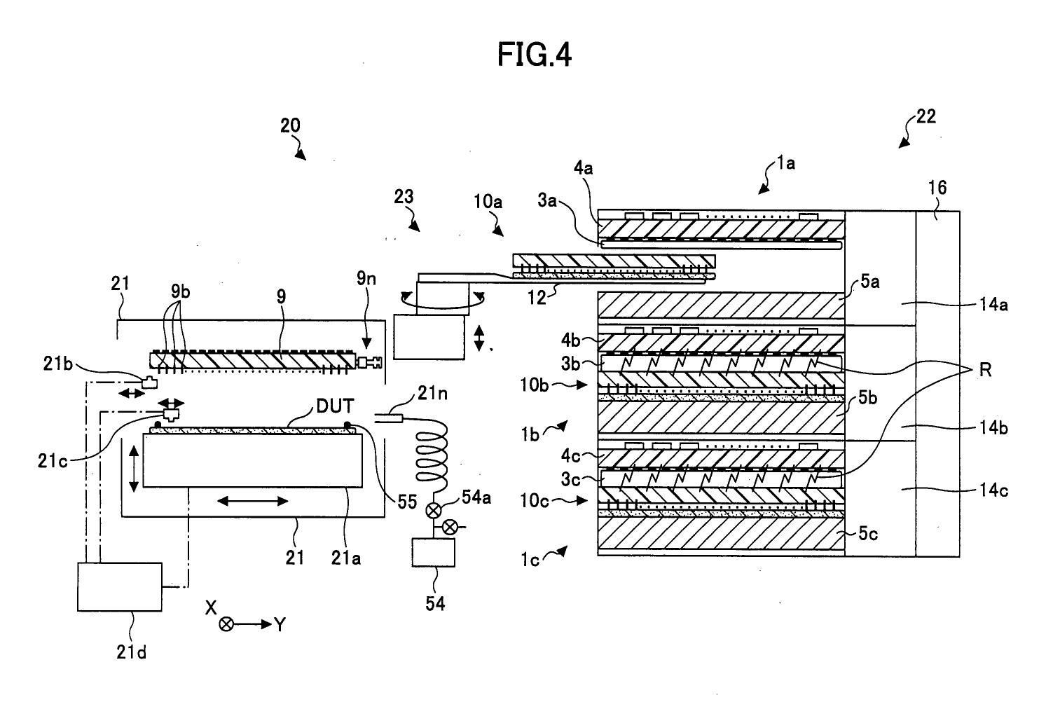

Next, a test system to which the test unit 1 is incorporated is explained with reference to FIG. 4. As shown, a test system 20 includes an alignment unit 21 where the probe board 9 and the device under test DUT are aligned with each other and formed into the shell 10 by temporarily fixing the probe board 9 and the device under test DUT, a test unit assembly 22 that accommodates the shell 10 and tests the device under test DUT, and a shell transfer mechanism 23 that transfers the shell 10 between the alignment unit 21 and the test unit assembly 22.

As shown in FIG. 4, the alignment unit 21 includes a stage on which the device under test DUT is placed, a camera 21b that takes an image of plural (e.g., four alignment marks) formed on the lower surface, on which the probes 9b are formed, of the probe board 9 that is held above the stage 21a, a camera 21c that takes an image of plural (e.g., four) alignment marks formed on the device under test DUT, a control unit 21d that specifies positions of the probe board 9 and the test under device DUT in X-Y coordinates, employing imaging analysis based on the images of the alignment marks taken by the cameras 21b, 21c.

The stage 21a is provided with plural (e.g., three) lift pins (not shown) that can move upward above or downward below an upper surface of the stage 21a, a chuck mechanism (not shown) that holds the device under test DUT placed on the upper surface of the stage 21a, and a driving mechanism (not shown) that moves the stage 21a in a horizontal (X or Y) direction or a vertical (Z) direction. The driving mechanism is electrically connected to a control unit 21d in order to move the stage 21a in the horizontal or the vertical direction under control of control signals from the control unit 21d.

The camera 21b is movable in the horizontal direction and can take the images, in series, of the alignment marks formed on the lower surface of the probe board 9 supported above the stage 21 with a predetermined supporting member (not shown). Image data of the alignment marks taken by the camera 21b are output to the control unit 21d.

Similarly, the camera 21c is movable in the horizontal direction. When the shell 10 is placed on the stage 21, the camera 21c moves in the horizontal direction and takes the images of the alignment marks formed on the device under test DUT of the shell 10 in series. Image data of the alignment marks taken by the camera 21c are output to the control unit 21d. Incidentally, a reference symbol 55 represents an elastic member (e.g., O-rings) made of a flexible elastic material such as silicon rubber, which is placed inside and along the circumferential edge of the device under test DUT.

Upon inputting the image data of the alignment marks from the cameras 21b, 21c, the control unit 21d specifies the positions of the probe board 9 and the device under test DUT in accordance with the images of the alignment marks. The control unit 21d calculates a shifting direction and shifting amount of the device under test DUT in accordance with a difference between the specified positions of the probe board 9 and the device under test DUT in order to align the device under test DUT with the probe board 9. In addition, the control unit 21d generates and outputs a control signal based on the calculation result to the driving mechanism (not shown) of the stage 21a. With this, the driving mechanism moves the stage 21a, thereby aligning the device under test DUT with the probe board 9.

Next, when the driving unit moves the stage 21a upward in accordance with another control signal from the control unit 21d, the electrode pads of the device under test DUT come close to the corresponding probes 9.

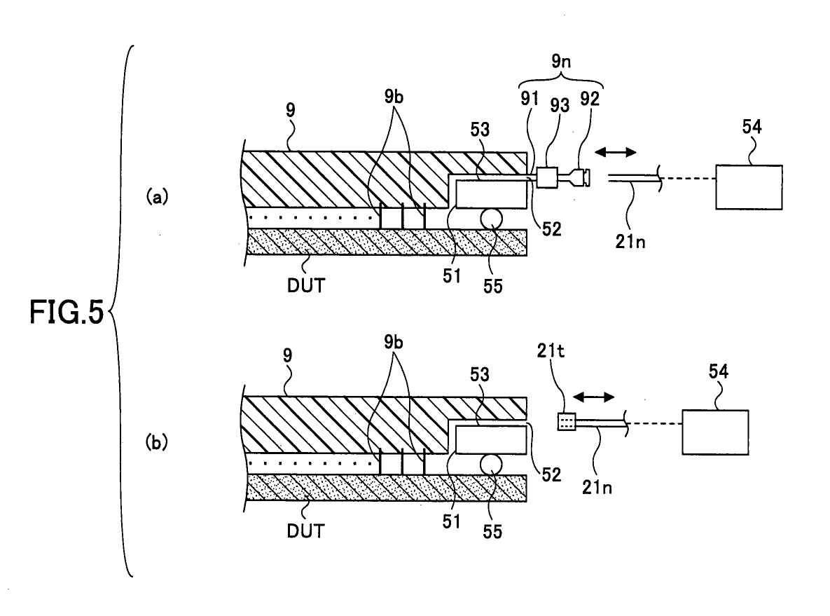

Subsequently, the device under test DUT and the probe board 9 are temporarily fixed with each other and thus the shell 10 is formed. Specifically, referring to a subsection (a) of FIG. 5, the probe board 9 is provided with a first port 51 open on a surface of the probe board 9, the surface facing the device under test DUT, a second port 52 open on a side surface of the probe board 9, and a conduit 53 that connects the first port 51 and the second port 52. In addition, a valve unit 9n is connected to the second port 52. The valve unit 9n includes a pipe 91 whose first end is connected to the second port 52, a detachable joint 92 connected to the other end of the pipe 91, and a check valve 93 provided in a middle portion of the pipe 91. In addition, a depressurization unit is provided corresponding to the valve unit 9n as shown in FIG. 4. The depressurization unit includes an evacuation unit 54 including, for example, a vacuum pump, a nozzle 21n that is connected to the evacuation unit 54 via a flexible pipe and detachably connected to the detachable joint 92 (FIG. 5), and a stop valve 54a provided in the middle of the flexible pipe. As shown in the subsection (a) of FIG. 5, when the nozzle 21n is fitted into the detachable joint 92 while the electrode pads of the device under test DUT are in contact with the corresponding probes 9b of the probe board 9, an inner space defined by the probe board 9, the device under test DUT, and the elastic member (O-ring) 55 is evacuated to a reduced pressure by the evacuation unit 54. With this, the elastic member 55 is deformed so that the inner space is sealed in an airtight manner. Because the check valve 93 is provided in the valve unit 9n, the inner space between the probe board 9 and the device under test DUT is maintained at a reduced pressure.

Incidentally, a thickness (height) of the circular elastic member 55 is determined so that the electrode pads of the device under test DUT can be in contact with the corresponding probes 9b of the probe board 9 after the elastic member 55 is deformed.

In the above manner, the probe board 9 and the device under test DUT are temporarily fixed and thus the shell 10 is formed by maintaining the inner space defined by the probe board 9, the device under test DUT, and the elastic member 55 at a reduced pressure. Incidentally, before the shell 10 is transferred from the alignment unit 21 to the test unit assembly 22 by the shell transfer mechanism 22, the nozzle 21n of the depressurization unit is detached from the detachable joint 92 of the valve unit 9n. Even in this case, the inner space can be maintained at a reduced pressure by the check valve 93.

The test unit assembly 22 is provided with three test units 1a, 1b, 1c; electric power sources 14a, 14b, 14c that supply electric power to the corresponding test units 1a, 1b, 1c; and a control unit 16 that controls the test unit 1a, 1b, 1c.

The test units 1a, 1b, 1c have the same configuration as the test unit 1 explained above, and operate on the electric power from the corresponding electric power sources 14a, 14b, 14c in the same manner as the test unit 1 under control of the control unit 16.

Referring again to FIG. 4, the shell transfer mechanism 23 is arranged between the test unit assembly 22 and the alignment unit 21, and can access the test units 1a, 1b, 1c of the test unit assembly 22 and the alignment unit 21. In addition, the shell transfer mechanism 23 has the transfer arm 12 explained above, with which the shell 10 is held and transferred between the test units 1a, 1b, 1c and the alignment unit 21.

In the test system 20 configured as explained above, after the electrode pads of the device under test DUT are aligned with the corresponding probes 9b of the probe board 9 in the alignment unit 21, the probe board 9 and the device under test DUT are temporarily fixed, and thus the shell 10 is configured of the probe board 9 and the device under test DUT. The shell 10 is transferred out from the alignment unit 21 and into any one of the test units 1a, 1b, 1c. The operations explained with reference to FIG. 3 are carried out with respect to the shell 10 in any one of the test units 1a, 1b, 1c, namely, electronic characteristics of the electronic circuits subject to testing of the device under test DUT of the shell 10 are tested. During the test for the shell 10 concerned, the next device under test DUT and another probe board 9 are aligned with each other in the alignment unit 21, temporarily fixed, and thus another shell 10 is formed. This next shell 10 is transferred into a remaining one of the test units 1a, 1b, 1c, into which no shell 10 has been transferred. Then, the same operations are carried out with respect to the next shell 10 in the remaining one of the test units 1a, 1b, 1c. In such a manner, the shells 10 are transferred one-by-one into the corresponding test units 1a, 1b, 1c, thereby enabling efficient testing of the electronic circuits subject to testing of the device under test DUT.

In addition, because the test units 1a, 1b, 1c are configured in the same manner as the test unit 1 explained with reference to FIGS. 1 through 3, the test units 1a, 1b, 1c can provide the same effects or advantages as the test unit 1 in the test system 20.

Moreover, because the alignment unit 21 is provided separately from the test units 1a, 1b, 1c, a need of aligning the electrode pads on the device under test DUT with the corresponding probes 9b (the subsection (b) of FIG. 1) of the probe board 9 in the test units 1a, 1b, 1c can be eliminated. If such alignment is carried out in the test units 1a, 1b, 1c, an alignment mechanism needs to be provided in each of the test units 1a, 1b, 1c, which makes the test system large in size and complicated, thereby increasing costs of the test system. However, the test system 20 according to this embodiment can be made compact, suppressing increased costs.

Incidentally, it is enough for the probe board 9 and the device under test DUT of the shell 10 to be kept in alignment with each other until the shell 10 is transferred into the test unit 1a (1b, 1c) by the shell transfer mechanism 22, placed on a chuck plate 5a (5, 5c) (FIG. 4) of the test unit 1a (1b, 1c), and pressed downward by an expandable chamber 3a (3b, 3c). In other words, it is enough that the probe board 9 and the device under test DUT are temporarily fixed so that the probes 9 and the corresponding electrode pads of the device under test DUT do not become misaligned until the temporarily fixed shell 10 is pressed downward by the expandable chamber 3a (3b, 3c) in the test unit 3a (3b, 3c). Therefore, when an inner diameter of the conduit 53 in the probe board 9 is sufficiently small, the check valve 93 is not necessary. In addition, the valve unit 9n may not be necessary, as shown in a subsection (b) of FIG. 5. In this case, it is preferable that a tip part 21t, which is made of a flexible material such as silicon rubber and has a through hole to be in gaseous communication with the second port 52 and the nozzle 21n, be attached at a distal end of the nozzle 21n. With this, when the tip part 21t is pressed onto the side surface of the probe board 9 so that the through hole of the tip part 21t is in gaseous communication with the conduit 53, the inner space defined by the probe board 9, the device under test DUT, and the elastic member (O-ring) 55 can be evacuated by the evacuation unit 54. With this, the elastic member 55 is pressed for deformation. In this case, the probe board 9 and the device under test DUT can be temporarily fixed due to tackiness of the elastic member 55, while there is no check valve 93 provided in the illustrated example in the subsection (b) of FIG. 5. After the tip part 21t is removed away from the side surface of the probe board 9, the shell 10 is transferred into any one of the test units 1a, 1b, 1c.

In addition, the probe board 9 and the device under test DUT may be temporarily fixed to form the shell 10 using magnets in the alignment unit 21, instead of evacuating the inner space defined by the probe board 9, the device under test DUT, and the elastic member 55. Alternatively, the shell 10 may be formed by clipping the probe board 9 and the device under test DUT using a predetermined clipping jig.

Incidentally, not only three but also two or four or more test units having the same configuration as the test unit 1 explained above may be stacked one on another in the test system 20. In addition, the test system 20 may have only one test unit.

Moreover, electric power for the wireless ports 9a of the probe board 9 may be supplied through wirings from the electric power sources 14a, 14b, 14c in the test unit assembly 22, or by electric power transmission through wireless ports for contactlessly transmitting electric power provided on corresponding lower surfaces of tester boards 4a, 4b, 4c (FIG. 4). Furthermore, the electric power may be supplied to the wireless ports 9a from the tester board 4 (4a, 4b, 4c) using pins having a length sufficient to reach the probe board 9, which are provided on areas of the lower surface of the tester board 4, the areas being away from the expandable chamber 3 (3a, 3b, 3c (FIG. 4)).

While the present invention has been described with reference to the several embodiments, the present invention is not limited to the above embodiments, but may be variously modified or altered within the scope of the accompanying Claims.

This international patent application contains subject matter related to U.S. Provisional Application No. 61/183,349 filed with the United State Patent and Trademark Office on Jun. 2, 2009, the entire contents of which are hereby incorporated herein by reference.

1. A test unit to be used with a tester that tests an electrical characteristic of an electronic circuit formed in a wafer, the test unit comprising:
a tester board that is accommodated in a system box and electrically connected to the tester;
a first wireless port that is mounted on a lower surface of the tester board and electrically connected to the tester;
a probe board that includes a probe to be in contact with an electrode pad of the electronic circuit, and is configured so that the probe board may be transferred along with the wafer into the system box while the probe and the electrode pad are in contact with each other;
a second wireless port that is mounted on an upper surface of the probe board electrically connected to the probe, and carries out contactless transmission/reception with the first wireless port:
a chuck plate that is accommodated in the system box in order to be away from the tester board, and holds the probe board and the wafer transferred into the system box; and
an expandable chamber having flexibility that allows the expandable chamber to be inflated by introducing gas thereinto, thereby applying pressure onto the probe board and wafer held by the chuck plate,
wherein the first wireless port is arranged in order to face the second wireless port via the expandable chamber, and test signals are contactlessly transmitted/received through the expandable chamber by the first and the second wireless ports.

2. A test system comprising:
the test unit claimed in claim 1;
an alignment unit that aligns the electrode pad of the electronic circuit fabricated on the wafer with the probe of the probe board and temporarily fixes the probe board and the wafer; and
a transfer unit that transfers the temporarily fixed probe board and wafer to the test unit.

3. The test system claimed in claim 2, wherein the alignment unit temporarily fixes the probe board and the wafer by reducing pressure in a space between the probe board and the wafer after aligning the electrode pad of the electronic circuit fabricated on the wafer with the probe of the probe board.

4. The test system claimed in claim 2, wherein the alignment unit temporarily fixes the probe board and the wafer with magnets after aligning the electrode pad of the electronic circuit fabricated on the wafer with the probe of the probe board.
